(19) United States
(12) Patent Application Publication
(10) Pub. No.: US 2024/0128239 A1
(43) Pub. Date: Apr. 18, 2024

(54) SEMICONDUCTOR PACKAGE

(71) Applicant: Samsung Electronics Co., Ltd., Suwon-si (KR)

(72) Inventors: Solji SONG, Suwon-si (KR); Junyun KWEON, Suwon-si (KR); Byeongchan KIM, Suwon-si (KR); Jumyong PARK, Suwon-si (KR); Dongjoon OH, Suwon-si (KR); Hyunchul JUNG, Suwon-si (KR); Hyunsu HWANG, Suwon-si (KR)

(73) Assignee: Samsung Electronics Co., Ltd., Suwon-si (KR)

(21) Appl. No.: 18/471,875

(22) Filed: Sep. 21, 2023

(30) Foreign Application Priority Data
Oct. 12, 2022 (KR) 10-2022-0130920

(51) Int. Cl. H01L 25/065; H01L 23/00; H01L 23/31; H01L 23/48; H01L 23/498

(52) U.S. Cl. CPC H01L 25/0657; H01L 23/3128; H01L 23/481; H01L 23/49822; H01L 24/08; H01L 24/16; H01L 2224/08145; H01L 2224/16227

(57) ABSTRACT

A semiconductor package includes a connection structure, a via protection layer on the connection structure, a first semiconductor chip on the via protection layer and including a first substrate having a first active face and a first inactive face opposite to each other a through-silicon via (TSV) configured to electrically connect the first semiconductor chip to the connection structure, and a second semiconductor chip on the first semiconductor chip and electrically connected to the first semiconductor chip. The second semiconductor chip includes a second substrate having a second active face and a second inactive face opposite to each other. The package includes a conductive post configured to electrically connect the second semiconductor chip and the connection structure with each other, and a molding layer filling a space between an upper surface of the connection structure and the second semiconductor chip, and the molding layer encloses the conductive post.

### CROSS-REFERENCE TO RELATED APPLICATION

This application claims priority under 35 USC § 119 to Korean Patent Application No. 10-2022-0130920, filed on Oct. 12, 2022, in the Korean Intellectual Property Office, the disclosure of which is incorporated by reference herein in its entirety.

### FIELD

Some example embodiments of the inventive concepts relate to a semiconductor package, including a semiconductor package including a plurality of semiconductor chips.

### BACKGROUND

Due to the great progress of the electronics industry and the user's requests, electronic devices have been downsized and lightened in weight, and for this purpose, semiconductor packages mounted on electronic products are desired or required to have various functions while their volume is gradually reduced. Accordingly, a semiconductor package has been developed to include a plurality of semiconductor chips.

### SUMMARY

Some example embodiments of the inventive concepts provide a semiconductor package for improving etching non-uniformity between manufacturing processes, for securing process reproducibility, and for reducing manufacturing cost.

Example problems that may be solved by the inventive concepts are not limited to the above-described problems.

According to an example embodiment of the inventive concepts, a semiconductor package includes a connection structure, a via protection layer on the connection structure, a first semiconductor chip on the via protection layer and including a first substrate having a first active face and a first inactive face opposite to each other, and the first semiconductor chip including a first back end of line (BEOL) layer on the first active face. The package includes a through-silicon via (TSV) configured to electrically connect the first semiconductor chip to the connection structure by at least partially penetrating the via protection layer, the first substrate, and the first active face, a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face, a conductive post configured to electrically connect the second semiconductor chip and the connection structure with each other, and a molding layer filling a space between an upper surface of the connection structure and the second semiconductor chip, and the molding layer enclosing the conductive post.

According to another example embodiment of the inventive concepts, a semiconductor package includes a connection structure, a via protection layer on the connection structure, a first semiconductor chip on the via protection layer and including a first substrate having a first active face and a first inactive face opposite to each other, and the first semiconductor chip including a first back end of line (BEOL) layer on the first active face, and a through-silicon via (TSV) configured to electrically connect the first semiconductor chip to the connection structure by at least partially penetrating the via protection layer, the first substrate, and the first active face. The package includes a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face, a conductive post configured to electrically connect the second semiconductor chip and the connection structure with each other, a molding layer filling a space between an upper surface of the connection structure and the second semiconductor chip, and the molding layer enclosing the conductive post, and a structure protection layer between the first semiconductor chip and the connection structure, and the structure protection layer covering a surface of the connection structure adjacent the molding layer. An overlap shape of the first semiconductor chip with respect to the upper surface of the connection structure is same as an overlap shape of the via protection layer with respect to the upper surface of the connection structure.

In addition, according to another example embodiment of the inventive concepts, a semiconductor package includes a connection structure, a via protection layer on the connection structure, a first semiconductor chip on the via protection layer and including a first substrate having a first active face and a first inactive face opposite to each other, and the first semiconductor chip including a first back end of line (BEOL) layer on the first active face, a through-silicon via (TSV) configured to electrically connect the first semiconductor chip to the connection structure by at least partially penetrating the via protection layer, the first substrate, and the first active face, a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face, a conductive post configured to electrically connect the second semiconductor chip and the connection structure with each other, and a molding layer filling a space between an upper surface of the connection structure and the second semiconductor chip and enclosing the conductive post. An overlap shape of the first semiconductor chip with respect to the upper surface of the connection structure is same as an overlap shape of the via protection layer with respect to the connection structure, the molding layer is in contact with all sides of the first semiconductor chip and all sides of the via protection layer, and the via protection layer includes an insulation material and encloses a circumference of the TSV protruding from the first inactive face of the first semiconductor chip.

### BRIEF DESCRIPTION OF THE DRAWINGS

Some example embodiments will be more clearly understood from the following detailed description taken in conjunction with the accompanying drawings in which:

FIG. 1 is a cross-sectional view illustrating a semiconductor package, according to an example embodiment.

FIG. 2 is a cross-sectional view illustrating a semiconductor package, according to an example embodiment.

FIGS. 3A to 3D are cross-sectional views illustrating sequential process steps for a method of manufacturing the semiconductor package, according to an example embodiment.

FIGS. 4A to 4D are cross-sectional views illustrating sequential process steps for a method of manufacturing the semiconductor package shown in FIG. 1, according to an example embodiment.

FIGS. 5A to 5E are cross-sectional views illustrating sequential process steps for a method of manufacturing the semiconductor package posterior to the processes shown in FIGS. 3A to 3D or in FIGS. 4A to 4D, according to an example embodiment.

### DETAILED DESCRIPTION

Hereinafter, some example embodiments of the inventive concepts will be described in detail with reference to the accompanying drawings. The same reference numerals are used for the same elements in the drawings, and the descriptions on the same elements are omitted.

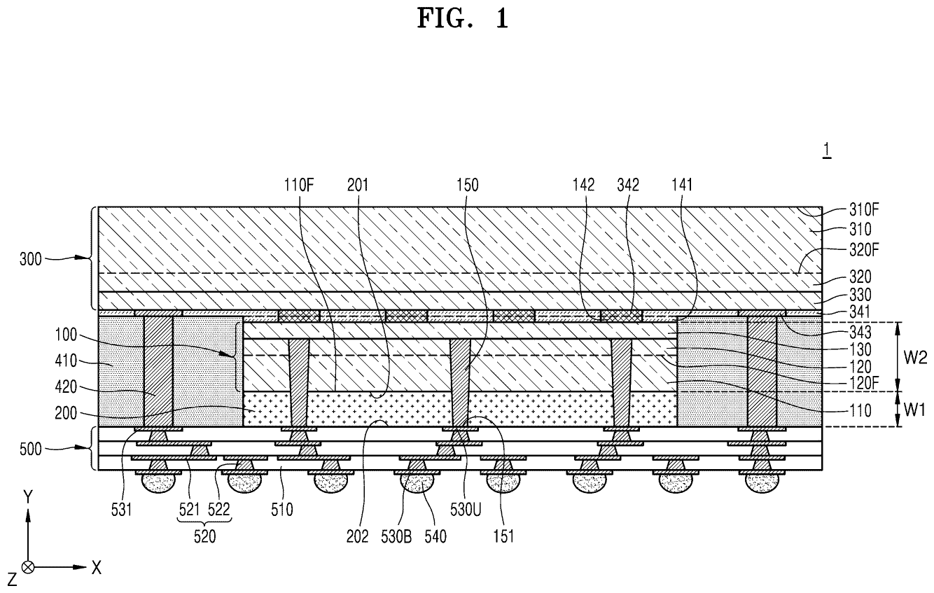

FIG. 1 is a cross-sectional view illustrating a semiconductor package 1 according to an example embodiment. Referring to FIG. 1, a semiconductor package 1 may include a first semiconductor chip 100, a via protection layer 200 in contact with the first semiconductor chip 100, a second semiconductor chip 300 positioned on an upper surface of the first semiconductor chip 100, and a connection structure 500 on which the via protection layer 200 is placed.

The semiconductor package 1 may include a fan-out semiconductor package in which the footprint of the connection structure 500 is larger than that of the first semiconductor chip 100. That is, the horizontal width and horizontal area of the connection structure 500 may have values greater than the horizontal width and horizontal area of the first semiconductor chip 100.

The connection structure 500 may electrically connect the first semiconductor chip 100 and the second semiconductor chip 300 to a plurality of external connection terminals 540. In another example embodiment, the connection structure 500 may include an interposer or a printed circuit board (PCB). In some example embodiments where the connection structure 500 is a portion of a redistribution structure, the connection structure 500 may include a redistribution layer (RDL) last structure. As will be described later, after the second semiconductor chip 300 is positioned on a carrier substrate (not shown), the first semiconductor chip 100 may be mounted on the second semiconductor chip 300 and the connection structure 500 may be positioned on the first semiconductor chip 100. Hereinafter, the connection structure 500 is described as to an example embodiment in which a redistribution structure is provided as the connection structure 500, however, the connection structure 500 is not limited to the redistribution structure.

The connection structure 500 may include a redistribution pattern 520 and a plurality of redistribution insulating layers 510 covering the redistribution pattern 520. The plurality of redistribution insulating layers 510 may be mutually stacked in a vertical direction (e.g., a Z-axis direction). The plurality of redistribution insulating layers 510 may include a material film of organic compounds. For example, each of the plurality of redistribution insulating layers 510 may include photo imageable dielectric (PID), Ajinomoto Build-up Film (ABF), or photosensitive polyimide (PSPI), but example embodiments are not limited thereto.

The redistribution pattern 520 may include a plurality of redistribution line patterns 521 that are arranged on at least one surface among upper and lower surfaces of each of the plurality of redistribution insulating layers 510, and a plurality of redistribution via patterns 522 extending through at least one of a plurality of redistribution insulating layers 510. The plurality of redistribution via patterns 522 may electrically connect the plurality of redistribution line patterns 521 positioned at different levels in the vertical direction (e.g., a Z-axis direction). For example, the redistribution pattern 520 may include a metal and an alloy thereof. Examples of the metal may include copper (Cu), aluminum (Al), tungsten (W), titanium (Ti), tantalum (Ta), indium (In), molybdenum (Mo), manganese (Mn), Cobalt (Co), tin (Sn), nickel (Ni), magnesium (Mg), rhenium (Re), beryllium (Be), gallium (Ga), and ruthenium (Ru), etc. However, the material of the redistribution pattern 520 is not limited to the materials described above.

Some of the plurality of redistribution line patterns 521 are provided on an upper surface of the connection structure 500, and may be connected to a conductive pad 530U that is connected to a TSV 150 that is to be described in detail hereafter, and connected to a conductive pad 531 connected to a post 420 that is also to be described in detail hereinafter. In addition, some of the plurality of redistribution line patterns 521 may be provided on a lower surface of the connection structure 500, to thereby form connection pads 530B that are connected to external terminals 540. The external terminal 540 may include, for example, a solder ball and a solder bump.

At least some of the plurality of redistribution line patterns 521 may be formed together with some of the plurality of redistribution via patterns 522, and may be provided as an integral body together with the some of the plurality of redistribution via patterns 522. For example, some of the plurality of redistribution line patterns 521 may be integrally formed with the plurality of redistribution via patterns 522 making contact with a lower surface thereof.

In some example embodiments, each redistribution via pattern 522 may have a tapered shape where a horizontal width thereof is reduced in a direction from an upper side to a lower side thereof. That is, as the plurality of redistribution via patterns 522 approach the upper surface of the connection structure 500, the horizontal widths of the plurality of redistribution via patterns 522 narrow. In some example embodiments, the thickness of the connection structure 500 in a vertical direction (e.g., a Z-axis direction) may be in a range of about 30 μm to about 100 μm.

The via protection layer 200 may be positioned on the upper surface of the connection structure 500, and the first semiconductor chip 100 may be positioned on an upper surface of the via protection layer 200. The first semiconductor chip 100 may include a first substrate 110 having a first active face 120F and a first inactive face 110F opposite to each other, a first front end of line (FEOL) layer 120, and a first back end of line (BEOL) layer 130. A first semiconductor device may be formed on some of the first substrate 110 adjacent to the first active face 120F, the first FEOL layer 120, and the first BEOL layer 130. A surface of the first substrate 110 on which the first semiconductor device is not arranged may be referred to as the first inactive face 110F. The first inactive face 110F may be positioned to face the via protection layer 200 that is described in detail hereinafter.

The first substrate 110 may include a semiconductor material such as a group IV material, a compound of group III and group V materials, and a compound of group II and group VI materials. The group IV material may include, for example, silicon (Si), germanium (Ge), and silicon (Si)-germanium (Ge). The compound of group III-V materials may include, for example, gallium arsenide (GaAs), indium phosphide (InP), gallium phosphide (GaP), indium arsenide (InAs), indium antimony (InSb), and indium gallium arsenide (InGaAs). The compound of group II-VI materials may include, for example, zinc telluride (ZnTe) and cadmium sulfide (CdS). However, example embodiments are not limited to the above materials.

The first semiconductor device may include, for example, a memory device and/or a logic device. For example, the memory device may include a dynamic random access memory (DRAM) device, a static random access memory (SRAM) device, a flash memory device, an electrically erasable and programmable read-only memory (EEPROM) device, a phase-change random access memory (PRAM) device, a magnetic random access memory (MRAM) device, a resistive random access memory (RRAM) device, and a combination thereof. The logic element may include, for example, a central processing unit (CPU), a graphic processing unit (GPU), a controller, an application specific integrated circuit (ASIC), an application processor processor (AP), and a combination thereof. However, example embodiments are not limited to the above memory and logic devices.

In some example embodiments, the first semiconductor chip 100 may further include a through-silicon via (TSV) 150 penetrating through at least a portion of the first substrate 110 and the first FEOL layer 120. The TSV 150 may include a conductive plug penetrating through the first substrate 110 and the first FEOL layer 120 and a conductive barrier layer (not shown) surrounding the conductive plug. The conductive plug may have a circular pillar shape, and the conductive barrier layer may have a cylindrical shape enclosing a sidewall of the conductive plug.

A cross-sectional area of the TSV 150 may be greater at an upper portion of the first semiconductor chip 100 than at a lower portion of the first semiconductor chip 100 for the manufacturing specifications or requirements of the semiconductor package. That is, the closer the TSV 150 comes to the connection structure 500, the smaller the cross-sectional area of the TSV 150 is. The configurations of the TSV 150 are not limited to the example descriptions given in the present specification.

The second semiconductor chip 300 may be electrically connected to the first semiconductor chip 100 and positioned on the first semiconductor chip 100. The second semiconductor chip 300 may include a second substrate 310 having a second active face 320F and a second inactive face 310F opposite to each other, a second FEOL layer 320, and a second BEOL layer 330. A second semiconductor device may be formed on some of the second substrate 310 adjacent to the second active face 320F, the second FEOL layer 320, and the second BEOL layer 330. The second semiconductor chip 300 may be positioned on the first semiconductor chip 100 in such a configuration that the first active face 120F of the first semiconductor chip 100 and the second active face 320F of the second semiconductor chip 300 face each other.

The second substrate 310 may include a semiconductor material, such as a group IV material, a compound of group III-V materials, and a compound of group II-VI materials. The group IV material may include, for example, silicon (Si), germanium (Ge), and silicon (Si)-germanium (Ge). The compound of group III-V materials may include, for example, gallium arsenide (GaAs), indium phosphide (InP), gallium phosphide (GaP), indium arsenide (InAs), indium antimony (InSb), and indium gallium arsenide (InGaAs). The compound of group II-VI materials may include, for example, zinc telluride (ZnTe) and cadmium sulfide (CdS). However, example embodiments are not limited to the above materials.

The second semiconductor device may include, for example, a memory device and/or a logic device. For example, the memory device may include a dynamic random access memory (DRAM) device, a static random access memory (SRAM) device, a flash memory device, an electrically erasable and programmable read-only memory (EEPROM) device, a phase-change random access memory (PRAM) device, a magnetic random access memory (MRAM) device, a resistive random access memory (RRAM) device, and a combination thereof. The logic element may include, for example, a central processing unit (CPU), a graphic processing unit (GPU), a controller, an application specific integrated circuit (ASIC), an application processor (AP), and a combination thereof. However, example embodiments are not limited to the above memory and logic devices.

The first semiconductor chip 100 may transmit/receive electrical signals with the outside (e.g., with devices other than the semiconductor package 1), through the external connection terminals 540 connected to the outside via the TSV 150, the conductive pad 530U, and the connection structure 500. The first semiconductor chip 100 may transmit/receive electrical signals via the second semiconductor chip 300, the first bonding pad 142 and the second bonding pad 342. The second semiconductor chip 300 may transmit/receive electrical signals with the outside via the conductive post 420, the connection structure 500 and the external connection terminal 540.

The via protection layer 200 may be positioned between the first semiconductor chip 100 and the connection structure 500. The via protection layer 200 may be in contact with the first inactive face 110F of the first semiconductor chip 100. The TSV 150 may penetrate through at least a portion of the via protection layer 200 while penetrating through at least a portion of the first semiconductor chip 100. The via protection layer 200 may cover side surfaces of the TSVs 150 that are protruded from the first semiconductor chip 100. The via protection layer 200 may be formed to make direct contact with the upper surface of the connection structure 500 on the side of the first semiconductor chip 100.

The via protection layer 200 may be coplanar or substantially coplanar with a side surface of the first semiconductor chip 100 in contact with the molding layer 410. The expression that two faces are coplanar means that the two faces may lie on the same or substantially the same plane. In other words, a surface extending from a side surface of the via protection layer 200 may be the same or substantially the same surface as a surface extending from the side surface of the first semiconductor chip 100. An overlap shape of the via protection layer 200 and the connection structure 500 may be the same or substantially the same as an overlap shape of the connection structure 500 and the first semiconductor chip 100.

The via protection layer 200 may include an insulating material. In an example embodiment, the via protection layer 200 may include a polymer. In an example embodiment, the via protection layer 200 may include a curable polymer. A curable polymer indicates a polymer obtained by an irreversible curing process to a soft solid polymer or a viscous liquid polymer. The curing process may be performed by various methods such as heating and UV irradiation.

A second surface 202 of the via protection layer 200, which is opposite to a first surface 201 making contact with the first inactive face 110F, may be formed at the same or substantially the same level as a first end surface 151 of the TSV 150 that is protruded from the first inactive face 110F among both ends of the TSV 150. In other words, the second surface 202 of the via protection layer 200, which is opposite to the first surface 201 making contact with the first inactive face 110F, may be coplanar or substantially coplanar with the first end surface 151 of the TSV 150.

A surface of the molding layer 410, which is close to the connection structure 500, may be formed at the same or substantially the same level as the second surface 202 and the first end surface 151 of the TSV 150. Thus, the surface of the molding layer 410 close to the connection structure 500, the second surface 202, and the first end surface 151 of the TSV 150 may be coplanar or substantially coplanar with one another.

A first thickness w1, which is a thickness of the via protection layer 200 in the vertical direction, indicates a thickness in the Z-axis direction between the first inactive face 110F and a surface of the via protection layer 200 making contact with the connection structure 500. The thickness of the semiconductor package 1 may vary according to the first thickness w1. In an example embodiment, the first thickness w1 of the via protection layer 200 may be equal to or smaller than the second thickness w2 of the first semiconductor chip 100. For example, the first thickness w1 may be greater than or equal to about 3 μm and less than or equal to about 20 μm.

The second semiconductor chip 300 may be electrically connected to the first semiconductor chip 100 by the first bonding pad 142 and the second bonding pad 342. The second semiconductor chip 300 may be connected to the connection structure 500 via the first semiconductor chip 100. For example, the second semiconductor chip 300 may be connected to the connection structure 500 via the second bonding pad 342, the first bonding pad 142, the TSV 150, and the conductive pad 530U. In addition, in some example embodiments, the second semiconductor chip 300 may be connected to the connection structure 500 by a conductive post 420 that is described in detail hereinafter. For example, the second semiconductor chip 300 may be connected to the connection structure 500 via the conductive pad 343, the conductive post 420, and the conductive pad 531.

The molding layer 410 may be positioned on the upper surface of the connection structure 500. The molding layer 410 may be positioned between the connection structure 500 and the second semiconductor chip 300, and may enclose the first semiconductor chip 100 and the via protection layer 200. In an example embodiment, the molding layer 410 may be formed to cover all side surfaces of the first semiconductor chip 100. The molding layer 410 may also be formed to cover all side surfaces of the via protection layer 200. The molding layer 410 may be formed to directly contact at least a portion of the upper surface of the connection structure 500 that is close to the first semiconductor chip 100.

In an example embodiment, the molding layer 410 may include a material resistive to a temperature of about 300° C. or higher and having a thermal expansion coefficient of about 10 ppm/° C. or less. The molding layer 410 may include an organic insulating material, such as an epoxy resin, a silicone resin, and a combination thereof. The molding layer 410 may include, for example, an epoxy mold compound (EMC). In some example embodiments, a side surface of the molding layer 410 may be coplanar or substantially coplanar with a side surface of the second semiconductor chip 300. In some example embodiments, the side surface of the molding layer 410 may be coplanar or substantially coplanar with a side surface of the connection structure 500.

The conductive post 420 may extend between the connection structure 500 and the conductive pad 343. The conductive post 420 may provide an electrical path between the second semiconductor chip 300 and the connection structure 500. The conductive post 420 may include, for example, a metal material, such as copper (Cu), silver (Ag), gold (Au), tungsten (W), aluminum (Al), titanium (Ti), tantalum (Ta), lead (Pb), tin (Sn), and a combination thereof, but example embodiments are not limited thereto. Although disclosed in a pillar shape in FIG. 1, the conductive post 420 may have any other shapes such as a bump shape.

The first bonding pad 142 may be positioned on the first semiconductor chip 100. A first bonding insulating layer 141 may enclose side surfaces of the first bonding pad 142. The first bonding insulating layer 141 may be positioned on the first semiconductor chip 100. A side surface of the first bonding insulating layer 141 may be coplanar or substantially coplanar with a side surface of the first semiconductor chip 100. In another example embodiment, the first bonding insulating layer 141 may extend onto the second coupling insulating layer 341, which is to be described in detail hereinafter, in such a configuration that the first bonding insulating layer 141 makes contact with an upper surface of the molding layer 410, unlike the configuration illustrated in the drawing. The configuration of the first bonding insulating layer 141 is not limited to the example embodiments described in the present specification.

The second bonding pad 342 and the conductive pad 343 may be positioned on a lower surface of the second semiconductor chip 300. A second bonding insulating layer 341 may enclose the second bonding pad 342 and the conductive pad 343. The conductive pad 343 may be positioned on the conductive post 420 in such a configuration that the conductive pad 343 is electrically connected to the conductive post 420. The first bonding pad 142 may make direct contact with the second bonding pad 342. In some example embodiments, the first bonding insulating layer 141 may make direct contact with the second bonding insulating layer 341.

In an example embodiment, the first bonding pad 142 and the second bonding pad 342 may be bonded to each other by a diffusion bonding process, to thereby form an integrated bonding pad. In the diffusion bonding process for forming the integrated bonding pad, conductive material layers may be formed on facing surfaces of the first semiconductor chip 100 and the second semiconductor chip 300, respectively. The conductive material layers arranged on facing surfaces of the first semiconductor chip 100 and the second semiconductor chip 300, respectively, may be referred to as the first bonding pad 142 and the second bonding pad 342. The facing conductive material layers, that is, the first bonding pad 142 and the second bonding pad 342, may be bonded by the diffusion bonding process in which the metal atoms of the facing conductive material layers are diffused by heating, to thereby form the integrated bonding pad.

The first bonding pad 142 and the second bonding pad 342 may include a conductive metal material, for example, copper (Cu), silver (Ag), gold (Au), tungsten (W), aluminum (Al), titanium (Ti), tantalum (Ta), and a combination thereof. The first bonding insulating layer 141 and the second bonding insulating layer 341 may include an inorganic insulating material, such as silicon oxide, silicon nitride, silicon carbonitride, silicon oxynitride, and a combination thereof. However, example embodiments are not limited to the above materials.

The external connection terminal 540 may be positioned on the connection pad 530B. The external connection terminal 540 may be used to connect the semiconductor package 1 to surroundings (e.g., to devices other than the semiconductor package 1). In some example embodiments, the external connection terminal 540 may include a solder bump. The external connection terminal 540 may include, for example, a conductive material including tin (Sn), lead (Pb), copper (Cu), silver (Ag), and a combination thereof, but example embodiments are not limited thereto.

The connection pad 530B may be positioned on the lower surface of the connection structure 500 and may make contact with the external connection terminal 540. The connection pad 530B may include a metal and be referred to as an under bump metal (UBM). For example, the connection pad 530B may include copper (Cu), nickel (Ni), silver (Ag), chromium (Cr), titanium (Ti), and palladium (Pd), but example embodiments are not limited thereto.

Due to a manufacturing process derived from the structure of a semiconductor package according to an example embodiment, which will be described in detail hereinafter, uniformity differences of photoresist, incomplete photoresist coating, or incomplete wafer etching due to the peeling of photoresist may be reduced or eliminated in a manufacturing process of a package including a first semiconductor chip and a second semiconductor chip. In addition, according to an example embodiment of the inventive concepts, the number of process steps may decrease as compared with a conventional manufacturing process of a semiconductor package.

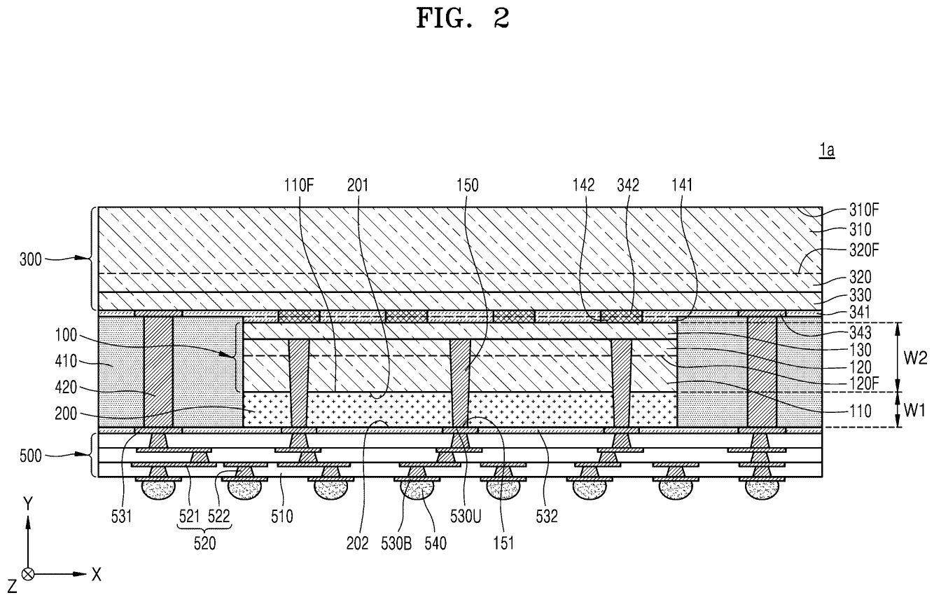

FIG. 2 is a cross-sectional view illustrating a semiconductor package 1a, according to an example embodiment. The same descriptions as given with reference to FIG. 1 will be omitted. Referring to FIG. 2, the semiconductor package 1a may include a first semiconductor chip 100, a via protection layer 200 in contact with the first semiconductor chip 100, a second semiconductor chip 300 on the upper surface of the first semiconductor chip 100 and a connection structure 500 on which a structure protection layer 532 is formed.

The structure protection layer 532 may be formed on the upper surface of the connection structure 500. The structure protection layer 532 may enclose the conductive pad 531, which is connected to the conductive post 420, and the conductive pad 530U which is connected to the TSV 150. One surface of the structure protection layer 532 may make contact with the connection structure 500 and the other surface of the structure protection layer 532 may make contact with the via protection layer.

The structure protection layer 532 may include, for example, oxide, nitride, polymer, and a combination thereof. In some example embodiments, the structure protection layer 532 may include oxide, nitride, and a combination thereof that is formed by a deposition process.

The via protection layer 200 may be positioned between the first semiconductor chip 100 and the structure protection layer 532. The via protection layer 200 may enclose side surfaces of the TSVs 150 protruding from the first semiconductor chip 100. The via protection layer 200 may make contact with the structure protection layer 532 and the conductive pad 530U on the opposite side of the first inactive face 110F of the first semiconductor chip 100.

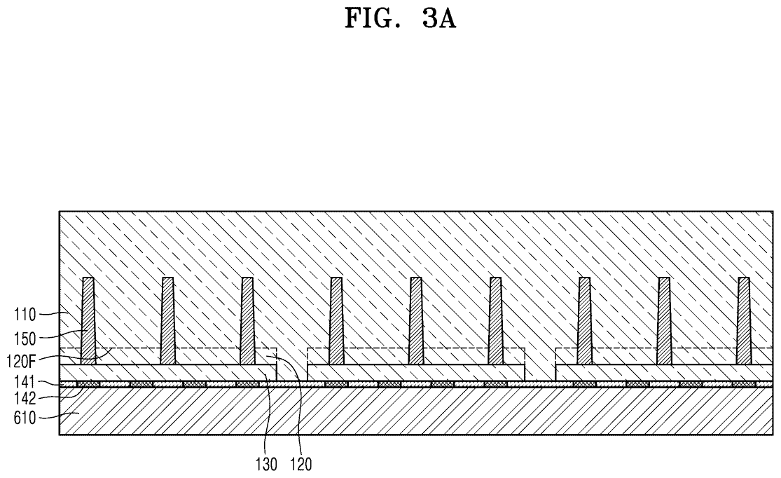

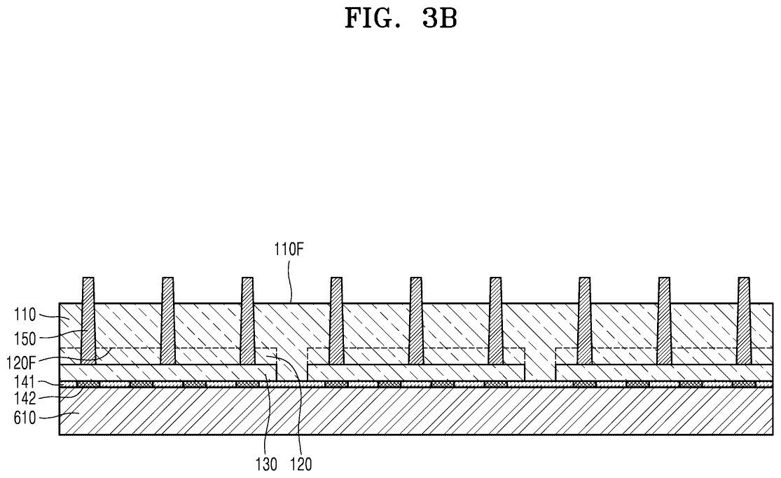

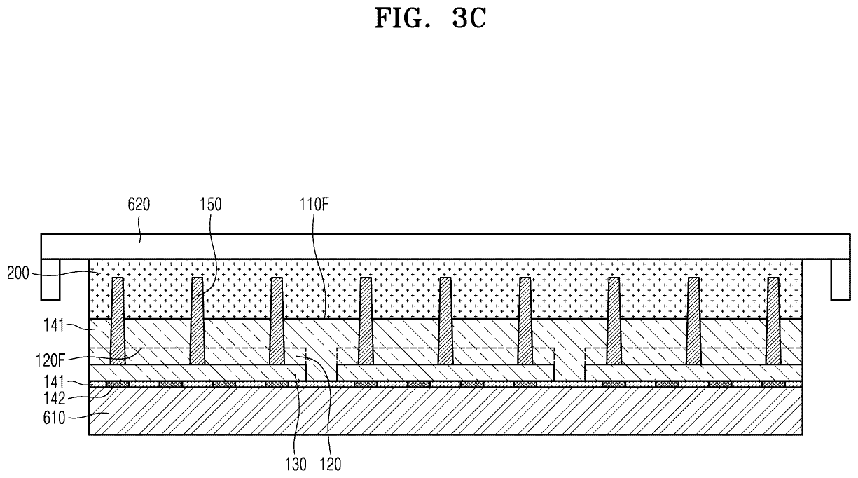

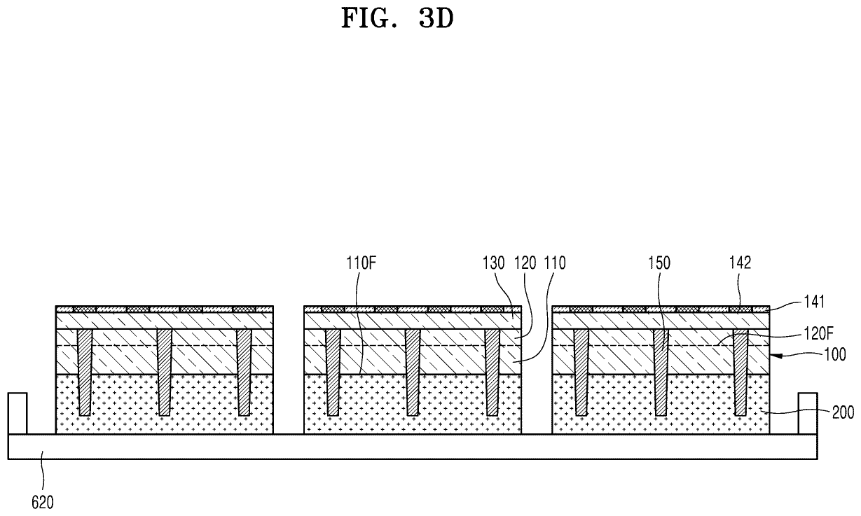

FIGS. 3A to 3D are cross-sectional views illustrating sequential process steps for a method of manufacturing the semiconductor package 1, according to an example embodiment. Hereinafter, the process steps are described in detail with a priority given to a method of manufacturing the semiconductor package 1 shown in FIG. 1. Thus, in FIGS. 3A to 3D, the same reference numerals denote the same elements in FIG. 1, and any further detailed descriptions on the same elements are omitted.

Referring to FIG. 3A, the TSV 150, the first FEOL layer 120, and the first BEOL layer 130 may be formed on the first substrate 110, and the first bonding pad 142 and the first bonding insulating layer 141 may be formed on the first BEOL layer 130. The first substrate 110 may be positioned on a carrier substrate (not shown) to which a lamination tape 610 is attached. The first substrate 110 may be adhered to the carrier substrate in such a configuration that the first BEOL layer 130 on which the first bonding pads 142 are formed faces the lamination tape 610, so that the first active face 120F faces downwards.

In another example embodiment, the first substrate 110 may be attached to the carrier substrate (not shown) by using a temporary adhesive for temporary bonding. The first substrate 110 may be adhered to the carrier substrate by the temporary adhesive in such a configuration that the first BEOL layer 130 on which the first bonding pads 142 are formed faces the carrier substrate, so that the first active face 120F faces downward.

Referring to FIG. 3B, the first substrate 110 may be partially removed in such a way that a plurality of the TSVs 150 is exposed. The first substrate 110 may be partially removed to thereby form the first inactive face 110F. That is, the first substrate 110 may be partially removed in such a way that the plurality of the TSVs 150 partially protrude from the first inactive face 110F.

Referring to FIG. 3C, the via protection layer 200 may be formed on an upper surface of the first substrate 110. As described above, the via protection layer 200a may be formed in such a way that the plurality of the TSVs 150, which are protruded from the first substrate 110, are enclosed by the via protection layer 200. Then, a back grinding tape for performing a back grinding (not shown) may be attached to a surface of the via protection layer 200, which is opposite to the first substrate 110, and then the via protection layer 200 may be positioned on the carrier substrate 620.

Referring to FIG. 3D, the carrier substrate to which the lamination tape 610 was attached is removed, and then the lamination tape 610 may be removed from the first substrate 110. The lamination tape 610 may be removed by irradiation of ultraviolet rays (UV). In addition, the first substrate 110 on which the via protection layer 200 is formed may be separated by a semiconductor chip in a dicing process, to thereby form a plurality of first semiconductor chips 100.

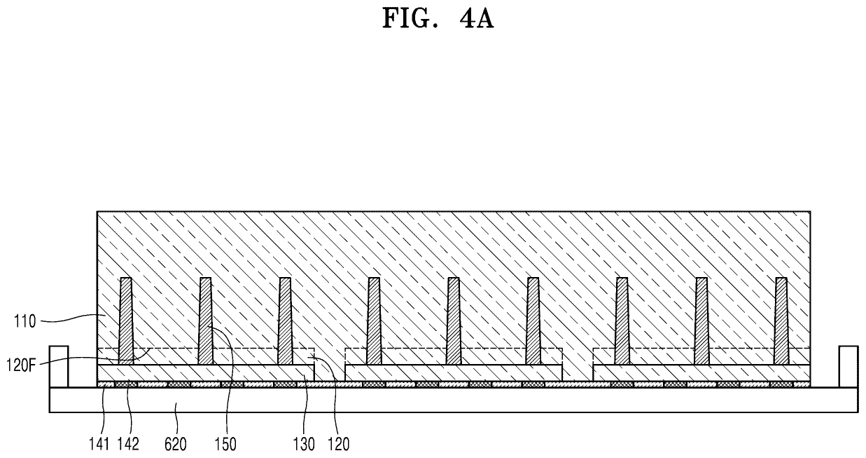

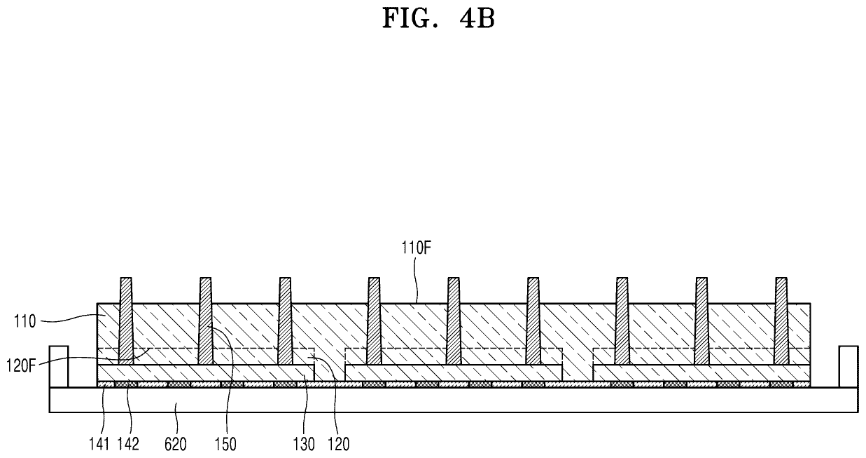

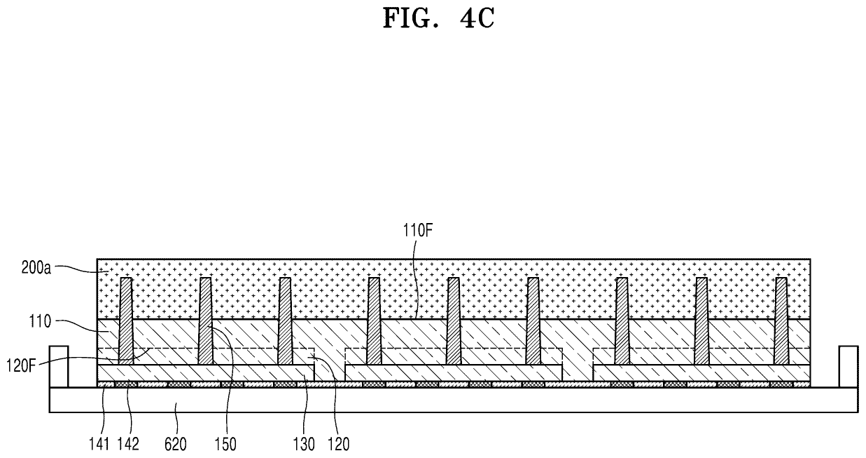

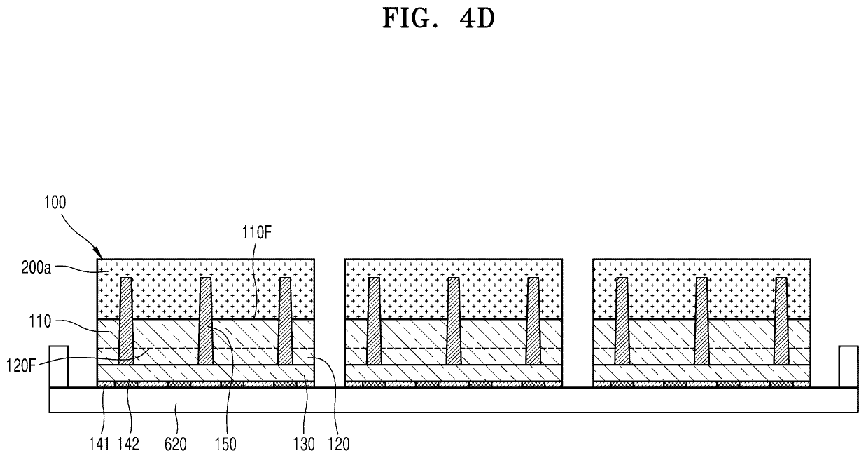

FIGS. 4A to 4D are cross-sectional views illustrating sequential process steps for a method of manufacturing the semiconductor package 1 shown in FIG. 1, according to an example embodiment. In FIGS. 4A to 4D, the same reference numerals denote the same elements in FIG. 1, and any further detailed descriptions on the same elements are omitted.

Referring to FIG. 4A, the TSV 150, the first FEOL layer 120, and the first BEOL layer 130 may be formed on the first substrate 110, and the first bonding pad 142 and the first bonding insulating layer 141 may be formed on the first BEOL layer 130. The first substrate 110 may be adhered to the carrier substrate 620 in such a configuration that the first BEOL layer 130 on which the first bonding pad 142 is formed faces the carrier substrate 620 on which the back grinding tape is arranged, so that the first active face 120F faces downwards.

Referring to FIG. 4B, the first substrate 110 may be partially removed in such a way that the plurality of the TSVs 150 are exposed. The first substrate 110 may be partially removed to thereby form the first inactive face 110F. That is, the first substrate 110 may be partially removed in such a way that the plurality of the TSVs 150 partially protrude from the first inactive face 110F.

Referring to FIG. 4C, a preliminary via protection layer 200a may be formed on the upper surface of the first substrate 110. As described above, the preliminary via protection layer 200a may be formed in such a way that the plurality of the TSVs 150, which is protruded from the first substrate 110, is enclosed by the preliminary via protection layer 200a.

Referring to FIG. 4D, the first substrate 110 and the preliminary via protection layer 200a may be separated by a semiconductor chip in a dicing process, to thereby form a plurality of first semiconductor chips 100.

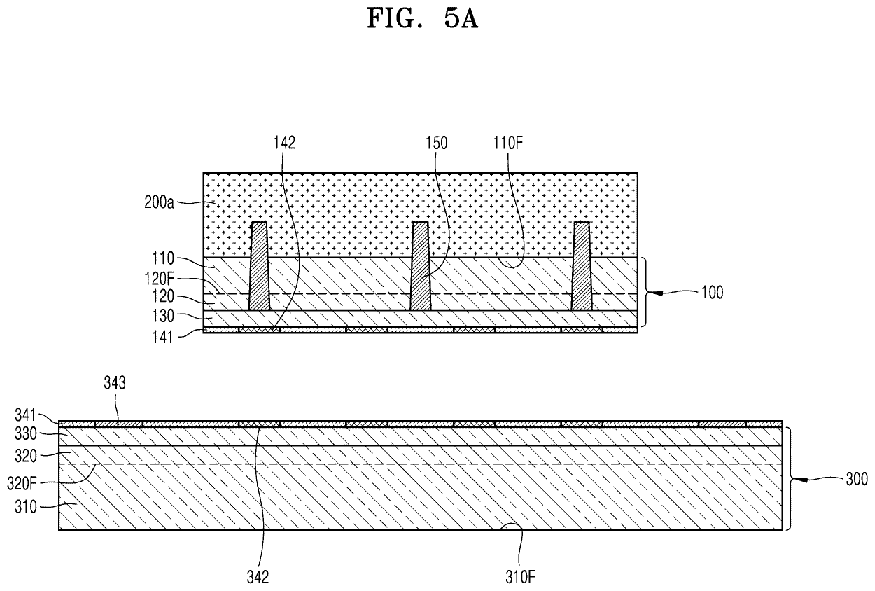

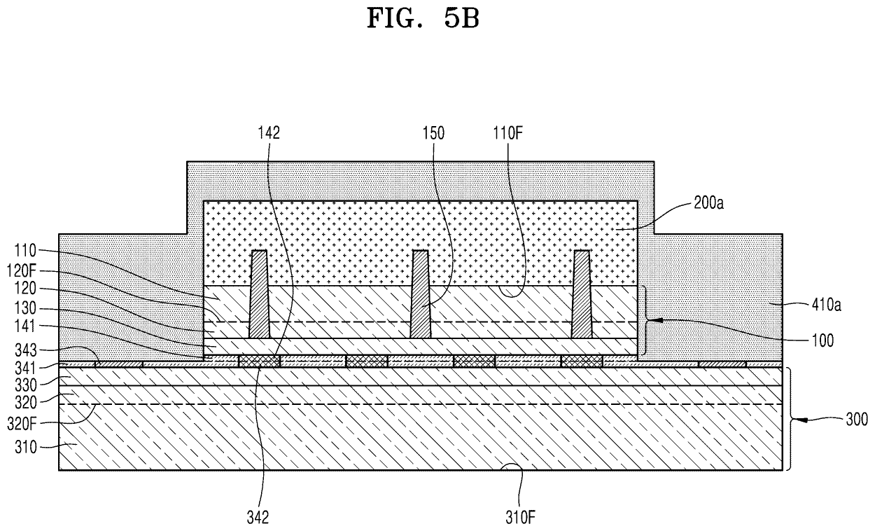

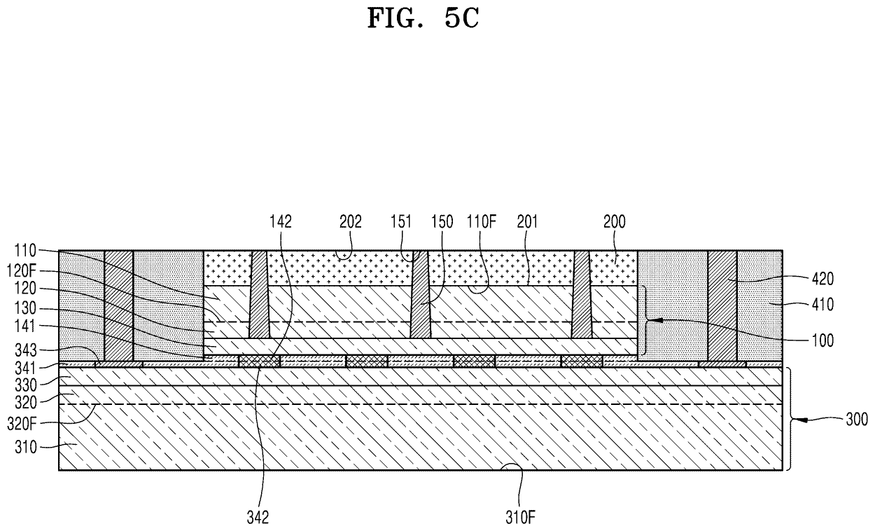

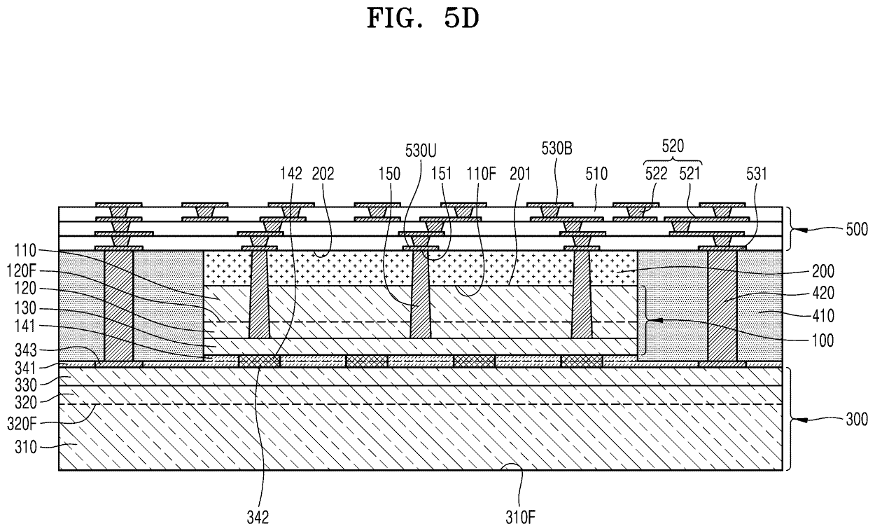

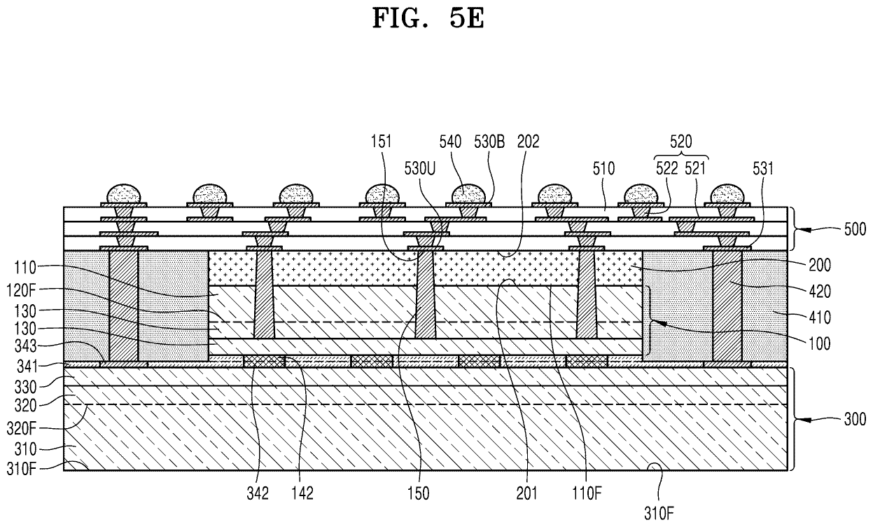

FIGS. 5A to 5E are cross-sectional views illustrating sequential process steps for a method of manufacturing the semiconductor package 1 in FIG. 1 including the semiconductor chip 100 having the preliminary via protection layer 200a formed by processes shown in FIGS. 3A to 3D or in FIGS. 4A to 4D, according to an example embodiment. In FIGS. 5A to 5E, the same reference numerals denote the same elements in FIG. 1, and any further detailed descriptions on the same elements are omitted.

Referring to FIG. 5A, the first semiconductor chip 100 having the preliminary via protection layer 200a may be mounted on the second semiconductor chip 300. The second semiconductor chip 300 may be positioned in such a way that the second BEOL layer 330 and the second FEOL layer 320 face the first semiconductor chip 100. The second bonding pad 342 on the second semiconductor chip 300 may make contact with the first bonding pad 142 on the first BEOL layer 130 of the first semiconductor chip 100. As described above, the first bonding pad 142 and the second bonding pad 342 may be formed to the integrated bonding pad by the diffusion bonding process.

Referring to FIG. 5B a preliminary molding layer 410a may be formed on the second semiconductor chip 300 by a chemical vapor deposition (CVD) process in such a way that the preliminary via protection layer 200a, the side surfaces of the first semiconductor chip 100, and the second bonding insulating layer 341 are covered with the preliminary molding layer 410a. As the first semiconductor chip 100 is positioned at a higher level than the second bonding insulating layer 341 on the second semiconductor chip 300, the preliminary molding layer 410a may be protruded along a surface profile of the first semiconductor chip 100 and the preliminary via protection layer 200a.

Referring to FIG. 5C, the preliminary molding layer 410a and the preliminary via protection layer 200a may be partially removed by a chemical mechanical polishing (CMP) process. Particularly, the TSVs 150 may be exposed on the via protection layer 200 by the CMP process. The upper surface of the molding layer 410, the first end surfaces 151 of the TSVs 150, and the second surface 202 of the via protection layer 200, which is opposite to the first surface 201 making contact with the first inactive face 110F, may be positioned at the same or substantially the same level in the vertical direction. In other words, the polished upper surface of the mold layer 410, the first end surfaces 151 of the TSVs 150, and the second surface 202 of the via protection layer 200 may be coplanar or substantially coplanar with one another.

The upper surface of the mold layer 410, the first end surfaces 151 of the TSVs 150, and the upper surface of via protection layer 200 may be patterned by a photolithography process, to thereby form a recess for forming the conductive post 420 in the molding layer 410. A conductive layer may be formed on the mold layer 410 to a sufficient thickness to fill up the recess by a physical vapor deposition (PVD) process or an electroplating process, and then, the conductive layer may be planarized by the CMP process until the upper surface of the mold layer 410 is exposed, to thereby form the conductive post 420 in the recess of the mold layer 410.

Referring to FIG. 5D, the connection structure 500 may be formed on the resultant structure described with reference to FIG. 5C. The connection structure 500 may include a plurality of stacked redistribution insulating layers 510 and a plurality of redistribution patterns 520 insulated by the plurality of redistribution insulating layers 510. The connection structure 500 may be formed by sequentially performing a first process step in which a conductive material layer is formed on the resultant structure described with reference to FIG. 5C and is patterned into a first floor redistribution line pattern 521, a second process step for forming a lower redistribution insulating layer 510 covering the first floor redistribution line pattern 521 and having a via hole through which the first floor redistribution line pattern 521 is exposed, and a third process step for forming the redistribution via pattern 522 in the via hole and a second floor redistribution line pattern 521 that extends on an upper surface of the lower redistribution insulating layer 510, while the second process step and the third process step are repeated many times. The conductive pad 531 in contact with the conductive post 420 may be formed together with the conductive pad 530U making contact with the TSV 150. Then, the under bump metallization (UBM, not shown) may be formed at a terminal area at which the external connection terminal 540 is located by a sputtering deposition process.

Referring to FIG. 5E, the external connection terminal 540 may be formed at the terminal area of the connection structure 500. For example, the external connection terminal 540 may include a bump shaped into a solder ball. A photoresist pattern may be formed on the connection structure 500 in such a way that the terminal area is exposed and a plating solution may be supplied in the terminal area defined by the photoresist pattern, to thereby form a plating layer on the terminal area of the connection structure 500. The plating solution may include a material having nickel (Ni), lead (Pb), and Tin (Sn), but example embodiments are not limited thereto. Then, the photoresist pattern may be removed, and the external connection terminal 540 may be formed by a reflow process.

A conventional manufacturing process for a semiconductor package is as follows. A first semiconductor chip is bonded onto a second semiconductor chip in forming the first semiconductor chip. A photoresist resist may be coated and patterned on the first semiconductor chip. Then, through the above patterning, the substrate corresponding to an inactive face of the first semiconductor chip may be partially etched off, thereby exposing TSVs from the inside of the first semiconductor chip. When the photoresist is coated, due to step differences of the thickness of the first semiconductor chip, the uniformity of the photoresist may not be constant, and there may be areas where the photoresist is not coated. In addition, the photoresist is often peeled off from the first semiconductor chip.

Thus, the etching process to the inactive face of the first semiconductor chip tends to be incomplete due to the non-uniformity of the photoresist layer, the incomplete coating of the photoresist, and the peeling of the photoresist layer. For example, when the inactive face of the first semiconductor chip is insufficiently etched at the corner points, a silicon wall tends to be formed at the corner points of the inactive face. That is, according to a conventional manufacturing process of a semiconductor package, etching uniformity in semiconductor chips is different from one another and the reproducibility of a semiconductor package decreases in the manufacturing process.

As described above, according to some example embodiments of the semiconductor package 1 manufactured by example inventive processes of manufacturing the semiconductor package 1, the first substrate 110 for forming the first semiconductor chip 100 is patterned until the TSVs 150, which have been arranged inside the first substrate, are exposed when forming the first semiconductor chip 100, which is different from a conventional process of manufacturing the semiconductor package. The via protection layer may be formed on the first substrate in such a way that the exposed TSVs are covered by the via protection layer, and then, the first substrate and the via protection layer may be simultaneously separated into a plurality of first semiconductor chips in the dicing process. The first semiconductor chip may be bonded to the second semiconductor chip, to thereby manufacture the semiconductor package 1.

According to an example embodiment of the manufacturing process of a semiconductor package, the incompleteness of the etching process to a wafer due to the non-uniformity of the photoresist layer, the incomplete coating of the photoresist, and the peeling of the photoresist layer, which are found when the manufacturing process is performed after the first semiconductor chip is mounted on the second semiconductor chip, may be reduced.

According to a conventional process of manufacturing the semiconductor package, the first semiconductor package is bonded to the second semiconductor package, and then, the inactive face of the first semiconductor package is etched off until the TSVs are exposed. The conventional process described above includes a photo process, an etching process, a photoresist removal process, a formation process of a protection layer for insulation, a chemical vapor deposition (CVD) process for forming a molding layer, and a mechanical chemical polishing (CMP) process.

According to an example embodiment of process of manufacturing the semiconductor package 1, the inactive face of the first semiconductor chip is etched until the TSVs, which have been arranged in the first semiconductor chip, may be exposed, and the via protection layer may be formed to enclose the exposed TSVs when forming the first semiconductor chip, which is different from a conventional manufacturing process of the semiconductor package. The via protection layer may be made of the same or substantially the same insulation material as the typical protection layer. As an operation of forming the photoresist layer, an operation of patterning the photoresist layer to the photoresist pattern, and an operation of etching the substrate until the TSVs are exposed are reduced in the inventive manufacturing process of the semiconductor package, the manufacturing cost may be significantly reduced.

The inventive concepts have been described with reference to some example embodiments shown in the drawings, and it will be understood by those skilled in the art that various modifications and equivalent other example embodiments are possible therefrom without changing technical ideas of the inventive concept. Therefore, the example embodiments described above should not be understood as limiting.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

While the inventive concepts have been shown and described with reference to some example embodiments thereof, it will be understood that various changes in form and details may be made therein without departing from the scope of the example embodiments.

What is claimed is:

1. A semiconductor package comprising:
a connection structure;
a via protection layer on the connection structure;
a first semiconductor chip on the via protection layer and including a first substrate having a first active face and a first inactive face opposite to each other, and the first semiconductor chip including a first back end of line (BEOL) layer on the first active face;
a through-silicon via (TSV) configured to electrically connect the first semiconductor chip to the connection structure by at least partially penetrating the via protection layer, the first substrate, and the first active face;
a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face;
a conductive post configured to electrically connect the second semiconductor chip and the connection structure with each other; and
a molding layer filling a space between an upper surface of the connection structure and the second semiconductor chip, and the molding layer enclosing the conductive post.

2. The semiconductor package of claim 1, wherein a surface extending from a side surface of the first semiconductor chip is same as a surface extending from a side surface of the via protection layer.

3. The semiconductor package of claim 1, wherein an overlap shape of the first semiconductor chip with respect to the upper surface of the connection structure is same as an overlap shape of the via protection layer with respect to the connection structure.

4. The semiconductor package of claim 3, wherein
the via protection layer includes an insulation material, and
the via protection layer encloses a circumference of the TSV protruding from the first inactive face of the first semiconductor chip.

5. The semiconductor package of claim 1, wherein the molding layer is in contact with all side surfaces of the first semiconductor chip and all side surfaces of the via protection layer.

6. The semiconductor package of claim 1, wherein the via protection layer includes curable polymer.

7. The semiconductor package of claim 4, wherein the first inactive face of the first semiconductor chip faces the via protection layer.

8. The semiconductor package of claim 4, wherein the via protection layer is in direct contact with a portion of the upper surface of the connection structure.

9. The semiconductor package of claim 4, wherein
a first end surface of the TSV protruding from the first inactive face is at a same level as a second surface of the via protection layer, and
the second surface is opposite to a first surface of the via protection layer that is in contact with the first inactive face.

10. The semiconductor package of claim 9, wherein a surface of the molding layer is at a same level as the first end surface and the second surface.

11. The semiconductor package of claim 1, wherein a thickness of the via protection layer is greater than or equal to a thickness of the first semiconductor chip in a vertical direction.

12. The semiconductor package of claim 1, further comprising:
a first bonding pad on a surface of the first semiconductor chip; and
a second bonding pad on a surface of the second semiconductor chip,
wherein the first bonding pad and the second bonding pad are diffusion bonded to each other to define an integrated bonding pad.

13. The semiconductor package of claim 1, wherein a cross-sectional area of the TSV on the first active face is larger than a cross-sectional area of the TSV on the first inactive face.

14. The semiconductor package of claim 1, wherein
the connection structure includes a redistribution structure,
the connection structure includes a redistribution line pattern and a redistribution via, and
the redistribution via has a tapered shape which narrows in a direction towards the via protection layer.

15. The semiconductor package of claim 1, wherein a thickness of the via protection layer in a vertical direction is in a range of 3 μm to 20 μm.

16. A semiconductor package comprising:
a connection structure;
a via protection layer on the connection structure;
a first semiconductor chip on the via protection layer and including a first substrate having a first active face and a first inactive face opposite to each other, and the first semiconductor chip including a first back end of line (BEOL) layer on the first active face;
a through-silicon via (TSV) configured to electrically connect the first semiconductor chip to the connection structure by at least partially penetrating the via protection layer, the first substrate, and the first active face;
a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face;
a conductive post configured to electrically connect the second semiconductor chip and the connection structure with each other;
a molding layer filling a space between an upper surface of the connection structure and the second semiconductor chip, and the molding layer enclosing the conductive post; and
a structure protection layer between the first semiconductor chip and the connection structure, and the structure protection layer covering a surface of the connection structure adjacent the molding layer,
wherein an overlap shape of the first semiconductor chip with respect to the upper surface of the connection structure is same as an overlap shape of the via protection layer with respect to the upper surface of the connection structure.

17. The semiconductor package of claim 16, wherein at least a portion of an upper surface of the structure protection layer, excluding an overlap area overlapping with the via protection layer, is in direct contact with the molding layer.

18. The semiconductor package of claim 17, wherein
the via protection layer includes an insulation material, and
the via protection layer encloses a circumference of the TSV protruding from the first inactive face of the first semiconductor chip.

19. A semiconductor package comprising:
a connection structure;
a via protection layer on the connection structure;
a first semiconductor chip on the via protection layer and including a first substrate having a first active face and a first inactive face opposite to each other, and the first semiconductor chip including a first back end of line (BEOL) layer on the first active face;
a through-silicon via (TSV) configured to electrically connect the first semiconductor chip to the connection structure by at least partially penetrating the via protection layer, the first substrate, and the first active face;
a second semiconductor chip on the first semiconductor chip and electrically connected to the first semiconductor chip, the second semiconductor chip including a second substrate having a second active face and a second inactive face opposite to each other, and the second semiconductor chip including a second BEOL layer on the second active face;
a conductive post configured to electrically connect the second semiconductor chip and the connection structure with each other; and
a molding layer filling a space between an upper surface of the connection structure and the second semiconductor chip and enclosing the conductive post, wherein
an overlap shape of the first semiconductor chip with respect to the upper surface of the connection structure is same as an overlap shape of the via protection layer with respect to the connection structure,
the molding layer is in contact with all sides of the first semiconductor chip and all sides of the via protection layer, and
the via protection layer includes an insulation material and encloses a circumference of the TSV protruding from the first inactive face of the first semiconductor chip.

20. The semiconductor package of claim 19, further comprising:
a first bonding pad on the first BEOL layer; and
a second bonding pad on the second BEOL layer, wherein
the first bonding pad and the second bonding pad are diffusion bonded to each other to define an integrated bonding pad,
a first end surface of the TSV protruding from the first inactive face is at a same level as a second surface of the via protection layer,
the second surface is opposite to a first surface of the via protection layer that is in contact with the first inactive face, and
the via protection layer includes a curable polymer.
